(19) United States
(12) Patent Application Publication
(10) Pub. No.: US 2026/0150224 A1
(43) Pub. Date: May 28, 2026

(54) WATERPROOF DEFLECTOR, WATERPROOF HEAT DISSIPATION ASSEMBLY, AND CABINET

(71) Applicant: HON HAI PRECISION INDUSTRY CO., LTD., New Taipei (TW)

(72) Inventors: KAI FAN CHIANG, New Taipei (TW); Chih-Cheng Lee, New Taipei (TW); Chiung-Hsiang Wu, New Taipei (TW); Chih-Te Hung, New Taipei (TW); Yu-Cheng Zhang, New Taipei (TW); Jyun-Lin Jiang, New Taipei (TW); Yi-Lun Wei, New Taipei (TW); Chung-Wei Lu, New Taipei (TW); Chen-Ting Kao, Taipei (TW); Sheng-Li Yen, New Taipei (TW); Chen Chao, New Taipei (TW); Cheng-Hung Chen, New Taipei (TW); Chi-Lin Wu, New Taipei (TW); Hsiu-Hao Cheng, New Taipei (TW); Chih-Hao Kuo, New Taipei (TW)

(21) Appl. No.: 19/003,141

(22) Filed: Dec. 27, 2024

(30) Foreign Application Priority Data
Nov. 27, 2024 (CN) 202411717704.0

(51) Int. Cl. H05K 7/20

(52) U.S. Cl. CPC H05K 7/20145; H05K 7/20154; H05K 7/20181

(57) ABSTRACT

A waterproof deflector is provided for blocking target objects carried by a flowing fluid. The waterproof deflector includes a body and a baffle. The body has a first end and a second end disposed opposite each other, defining a flow direction from the first end toward the second end. The baffle is inclinedly connected to the second end of the body and configured to block target objects in the fluid flowing along the flow direction. The angle between the baffle and the second end is from about 60° to about 120°. The first end is formed with a notch, configured to allow blocked target objects to be discharged. The disclosed waterproof deflector offers efficient target-object blocking capability, a simple structure, and strong adaptability. Also provided are a waterproof heat dissipation assembly and a cabinet

### FIELD

The present disclosure relates to the field of waterproof heat dissipation, and more particularly to a waterproof deflector, a waterproof heat dissipation assembly having the waterproof deflector, and a cabinet having the waterproof heat dissipation assembly.

### BACKGROUND

Outdoor enclosures, including charging station cabinets, may have waterproof structures to block rainwater from entering the enclosure. The waterproof structure may be a partition or an insulating box installed in the enclosure, and the main electric components are placed in the box.

However, such partition or insulating box may hinder heat dissipation from the internal electric components. Even if a fan is added to facilitate air circulations in the enclosure, the fan increases the size and the weight of the product, and may also require for more installation space.

### BRIEF DESCRIPTION OF THE DRAWINGS

Implementations of the present technology will now be described, by way of example only, with reference to the attached figures, wherein:

FIG. 1 is a schematic view of a cabinet according to an embodiment of the present disclosure.

FIG. 2 is a schematic view of a waterproof heat dissipation assembly of the cabinet shown in FIG. 1.

FIG. 3 is another perspective schematic view of the waterproof heat dissipation assembly shown in FIG. 2.

FIG. 4 is an exploded view of the waterproof heat dissipation assembly shown in FIG. 2.

FIG. 5 is a cross-sectional view of the waterproof heat dissipation assembly, taken along line V-V, in FIG. 2.

FIG. 6 is a schematic view of a waterproof deflector of the waterproof heat dissipation assembly shown in FIG. 3.

FIG. 7 is a schematic view illustrating a process of inserting the waterproof deflector shown in FIG. 6, into a first cover body of the waterproof heat dissipation assembly.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain portions have been exaggerated to better illustrate details and features of the present disclosure.

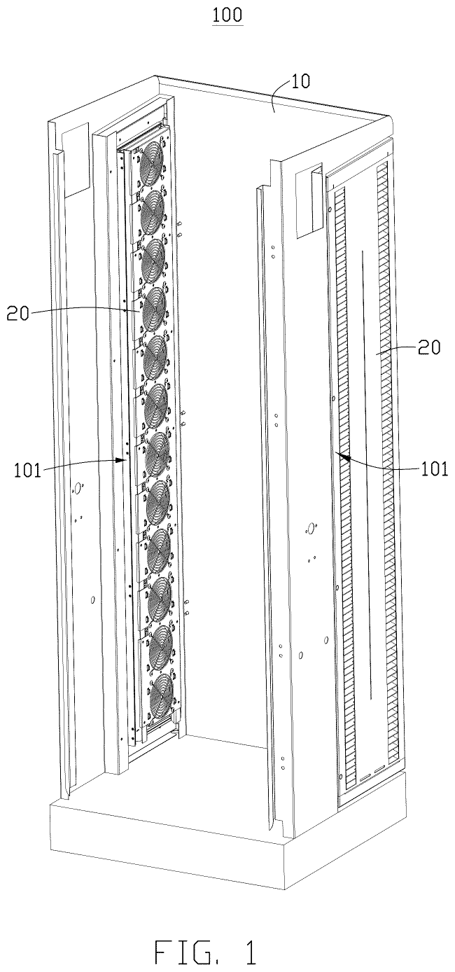

Referring to FIG. 1, a cabinet 100 is provided according to one embodiment of the present application. The cabinet 100 is suitable for use in outdoor charging station systems. In other embodiments, the cabinet 100 may be applied to a communication base, an outdoor meteorological monitoring station equipment, an outdoor multimedia display equipment cabinet in public spaces such as parks or plazas, an urban outdoor lighting control system cabinet, and an open-air factory automation monitoring equipment cabinet.

In some embodiment, the cabinet 100 includes a cabinet body 10 and at least two waterproof heat dissipation assemblies 20. The cabinet body 10 have at least two openings 101 accordingly, and each opening 101 is for accommodating one waterproof heat dissipation assembly 20. The waterproof heat dissipation assemblies 20 facilitate heat exchange between the interior of the cabinet body 10 and the external environment.

In some embodiment, there are two waterproof heat dissipation assemblies 20, one is configured to introduce external cool air into the cabinet 10, and the other is configured to exhaust heated air from the cabinet 10 into the external environment. In other embodiments, three or more waterproof heat dissipation assemblies 20 may be provided, with at least one for introducing cool external air and at least one for exhausting warm internal air.

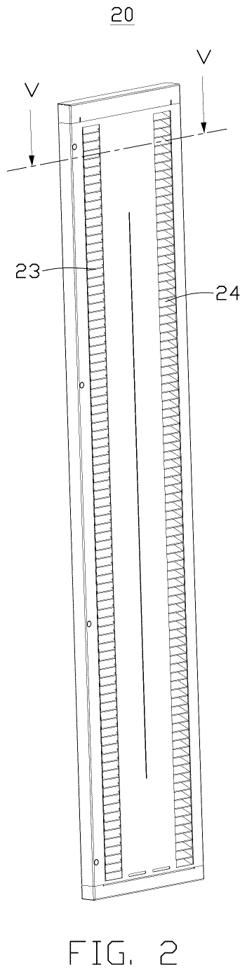

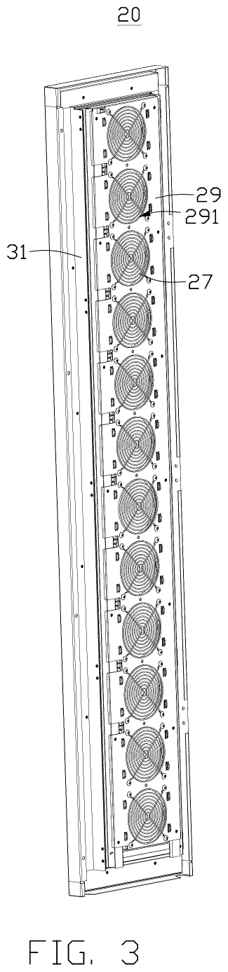

Referring to FIGS. 2-7, each waterproof heat dissipation assembly 20 is provided with a mounting plate 21, a first cover body 22, and a plurality of waterproof deflectors 23. The first cover body 22 is generally frame-shaped. The mounting plate 21 is disposed inside the first cover body 22 and extends along a direction A. The waterproof deflectors 23 are arranged side by side along the mounting plate 21, spaced apart along direction A. A Channel T is defined between adjacent waterproof deflectors 23. Through the channel T, heat exchange is permitted between hot air inside the cabinet 10 and cooler external air.

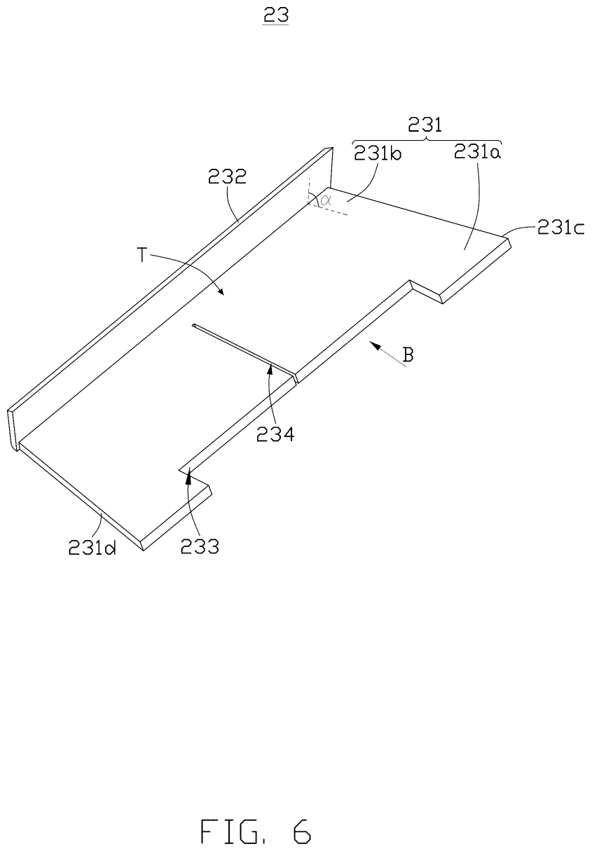

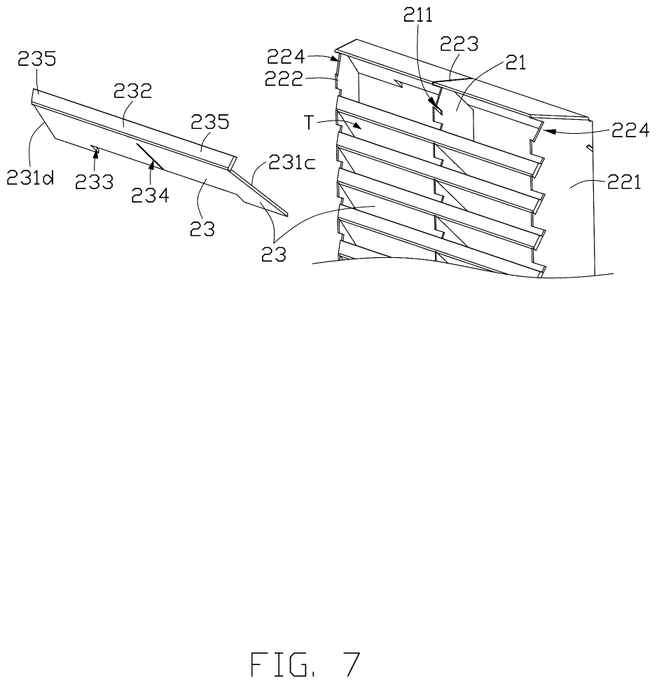

Referring to FIGS. 6 and 7, each waterproof deflector 23 is generally hook-shaped. Each waterproof deflector 23 includes a body 231 and a baffle 232. The body 231 includes a first end 231a and a second end 231b disposed opposite to each other. A flow direction B is defined from the first end 231a toward the second end 231b. Air is able to flow along the flow direction B within the channel T. The flow direction B is oblique relative to the direction A along which the mounting plate 21 extends. The baffle 232 is inclinedly connected at the second end 231b. By this configuration, target objects such as water, ice, or dust carried by the airflow are blocked. The first end 231a is formed with a notch 233. Multiple notches 233 are arranged along direction A. Because the flow direction B is inclined relative to direction A, target objects blocked by the baffle 232 can be discharged through the notches 233.

In some embodiment, perpendicular to the flow direction B, the body 231 includes a first side 231c and an opposite second side 231d. The first cover body 22 is frame-shaped and includes a first frame 221, a second frame 222, and two first connecting portions 223. The first frame 221 and the second frame 222 are spaced and parallel. The two first connecting portions 223 connect corresponding ends of the first frame 221 and the second frame 222. The first side 231c of the body 231 is connected to the side of the first frame 221 that faces the second frame 222. The second side 231d of the body 231 is connected to the side of the second frame 222 that faces the first frame 221. Thus, the first cover body 22 prevents airflow from escaping in the direction perpendicular to the flow direction B.

In some embodiment, an angle α between the baffle 232 and the body 231 is from about 60° to about 120°. Within this range, the baffle 232 can effectively block moisture, ice, dust, and other target objects. Excessive airflow obstruction is avoided. A smaller angle might reduce blocking efficiency, allowing some target objects to enter the cabinet 10. A larger angle might create undue airflow resistance, reducing the overall heat dissipation efficiency.

Perpendicular to the flow direction B, a cross-sectional width of the first end 231a is greater than that of the second end 231b. In this manner, the channel T narrows toward the second end 231b. As a result, external cool air entering the cabinet 10 accelerates. According to fluid dynamics principles, a reduced cross-sectional area under a given pressure difference increases fluid velocity. Thus, cooler external air enters the cabinet 10 more rapidly, enhancing heat dissipation and maintaining stable operation of internal components.

The body 231 is defines a plurality of fixing slots 234, one end of each fixing slot 234 communicates with the bottom of the notch 233. A portion of the mounting plate 21 is inserted into each fixing slot 234 to position the waterproof deflector 23. The mounting plate 21 is formed with a corresponding mounting slot 211. When the mounting plate 21 is inserted into the fixing slot 234, the mounting slot 211 and the fixing slot 234 fit together. An edge of the mounting plate 21 aligns substantially with the bottom of the notch 233. Thus, the mounting plate 21 does not intrude into the notch 233, reducing interference with the discharge path for target objects.

Additionally, in a direction perpendicular to the flow direction B, opposite ends of the baffle 232 protrude beyond the second end 231b. Positioning blocks 235 are thereby formed. The positioning blocks 235 fit into recesses 224 formed in the first frame 221 and the second frame 222. By this configuration, the waterproof deflectors 23 are secured in place. Displacement caused by airflow or external forces is prevented. Stable heat exchange and effective target-object blocking are maintained. Moreover, installation and removal of the waterproof deflectors 23 are simplified, facilitating maintenance or replacement.

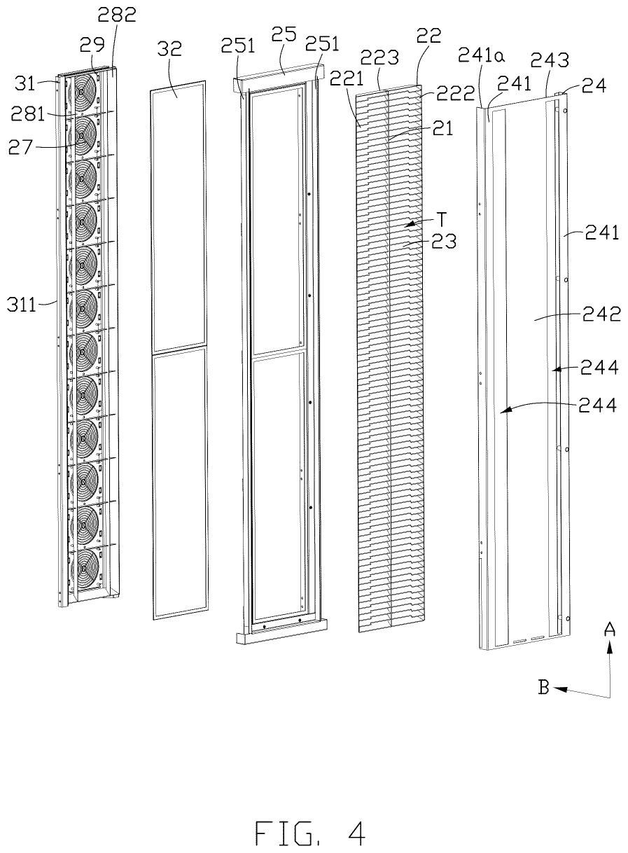

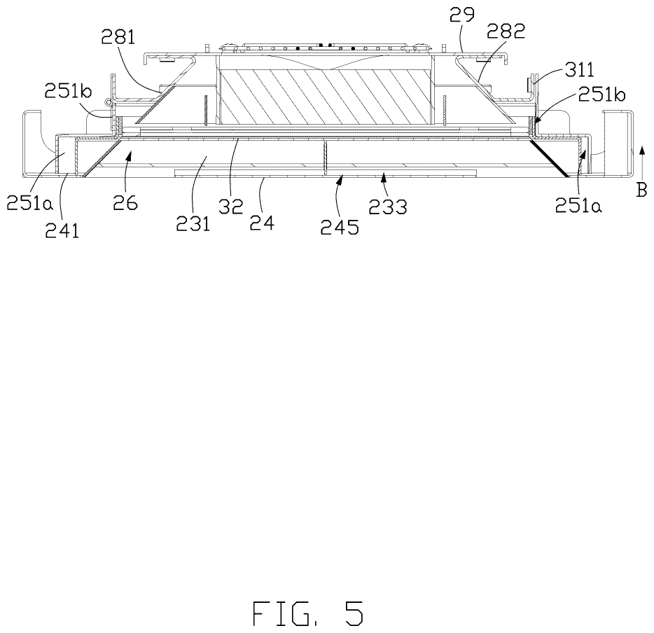

Referring to FIGS. 4 and 5, In some embodiment, the waterproof heat dissipation assembly 20 further includes a first housing 24 and a first housing frame 25. The first housing 24 and the first housing frame 25 define a first installation space 26. The first cover body 22 is disposed within the first installation space 26. The first housing 24 is generally U-shaped and includes two spaced side bars 241, a housing plate 242, and two connecting strips 243. The side bars 241 are arranged at intervals. The housing plate 242 is disposed between the side bars 241. The housing plate 242 is spaced from each side bar 241, thereby forming two ventilation openings 244 that communicate with the channel T. The housing plate 242 covers the notches 233 of multiple waterproof deflectors 23, forming a discharge channel 245 for target objects. The two connecting strips 243 connect the ends of the side bars 241 and the housing plate 242. The side bars 241 may bend to form edge strips 241a. One edge strip 241a can be pivotally connected to the cabinet body 10. By this arrangement, the waterproof heat dissipation assembly 20 can swing open for maintenance.

The first housing frame 25 includes two spaced first supporting plates 251 formed in a step-like shape. Each first supporting plate 251 includes a first step portion 251a and a second step portion 251b. The side bars 241 of the first housing 24 are connected to the first step portions 251a, thereby forming the first installation space 26.

Referring to FIGS. 2 and 5, the waterproof heat dissipation assembly 20 may include a fluid driving device 27, such as an axial flow fan, connected to the first housing frame 25. The fluid driving device 27 is configured to drive airflow along or opposite the flow direction B. For example, one waterproof heat dissipation assembly 20 can draw cool external air into the cabinet 10 along the flow direction B. Another waterproof heat dissipation assembly 20 can exhaust warm internal air out of the cabinet 10 opposite the flow direction B.

Referring to FIGS. 4 and 5, the waterproof heat dissipation assembly 20 may further include a second cover body 28 and a second housing 29. The second cover body 28 and the second housing 29 define a second installation space 30. The fluid driving device 27 is disposed in the second installation space 30, which communicates with the first installation space 26. The second cover body 28 may be similar in shape to the first cover body 22. The second cover body 28 includes a third frame 281, a fourth frame 282, and second connecting portions connecting the third frame 281 and the fourth frame 282. The second housing 29 is generally U-shaped. A plurality of through holes 291 is defined in the second housing 29. These through holes 291 communicate with the second installation space 30. The fluid driving device 27 faces the through holes 291.

The third frame 281 and the fourth frame 282 are spaced and inclined relative to each other. A cross section of the second cover body 28 along the flow direction B is thus funnel-shaped, narrowing along the flow direction B. Residual target objects are further blocked from reaching the fluid driving device 27. Therefore, damage risk is reduced, and reliable operation is ensured.

Referring to FIGS. 2-5, the waterproof heat dissipation assembly 20 may include a second housing frame 31 disposed between the first housing frame 25 and the second housing 29. The second housing frame 31 includes a second supporting plate 311. One side of the second supporting plate 311 is connected to the second housing 29. The other side of the second supporting plate 311 is pivotally connected to the second step portion 251b of the first supporting plate 251.

Referring to FIGS. 4 and 5, the waterproof heat dissipation assembly 20 may further include a filtering member 32 disposed on the second step portion 251b, between the fluid driving device 27 and the plurality of waterproof deflectors 23. The filtering member 32 can be a metallic mesh, such as a stainless steel mesh.

The cabinet 100 disclosed herein achieves optimized size and structural compactness. Rational arrangement of the waterproof heat dissipation assemblies 20 is provided. For instance, the first housing 24, the first housing frame 25, and other components are arranged without significantly increasing overall cabinet dimensions. The pivoted connection of the waterproof heat dissipation assemblies 20 to the cabinet body 10 allows easy opening for maintenance. Unnecessary protrusions are avoided, and a neat and efficient cabinet profile is maintained.

The embodiments shown and described above are only examples. Many details are often found in the art such as the other features of the waterproof deflector 23. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the portions within the principles of the present disclosure up to, and including the full extent established by the broad general meaning of the terms used in the claims. It will therefore be appreciated that the embodiments described above may be modified within the scope of the claims.

What is claimed is:

1. A waterproof deflector configured for blocking target objects in a fluid, the waterproof deflector comprising:
a body comprising a first end and a second end opposite to each other, a direction from the first end to the second end being defined as a flow direction; and
a baffle connected to the second end, the baffle configured to block the target objects in the fluid flowing along the flow direction, and an angle between the baffle and the second end in a range from about 60°to about 120°;
wherein the first end comprises a notch, and the notch is configured to allow for discharging the target objects from the waterproof deflector.

2. The waterproof deflector of claim 1, wherein, in a direction perpendicular to the flow direction, a cross-sectional width of the first end is greater than a cross-sectional width of the second end.

3. The waterproof deflector of claim 1, wherein the body defines a fixing slot having one end in communication with the notch, and the waterproof deflector is positioned in the fixing slot.

4. The waterproof deflector of claim 1, wherein, in a direction perpendicular to the flow direction, two ends of the baffle protrude from the second end of the body and form positioning blocks, and the positioning blocks are configured to position the waterproof deflector.

5. A waterproof heat dissipation assembly comprising:
a plurality of waterproof deflectors, each of the plurality of waterproof deflectors comprising:
a body comprising a first end and a second end disposed opposite each other, a flow direction being defined from the first end toward the second end;
a baffle connected to the second end of the body, the baffle being configured to block target objects carried by a fluid flowing along the flow direction; and
wherein an angle between the baffle and the second end is about 60° to about 120°, and the first end is formed with a notch configured to allow blocked target objects to be discharged;
a mounting plate comprising a plurality of mounting slots spaced from each other, each of the plurality of mounting slots extending in a same direction, wherein the plurality of waterproof deflectors is inserted into the plurality of mounting slots, respectively; and
a first cover body surrounding the mounting plate and the plurality of waterproof deflectors.

6. The waterproof heat dissipation assembly of claim 5, wherein, in a direction perpendicular to the flow direction, a cross-sectional width of the first end is greater than a cross-sectional width of the second end.

7. The waterproof heat dissipation assembly of claim 5, wherein the body further comprises a fixing slot having one end in communication with the notch, the fixing slot is configured to affix the waterproof deflector in a location.

8. The waterproof heat dissipation assembly of claim 5, wherein, in a direction perpendicular to the flow direction, opposite ends of the baffle protrude from the second end and form positioning blocks configured to affix the waterproof deflector in a location.

9. The waterproof heat dissipation assembly of claim 5, further comprising a first housing and a first housing frame, wherein the first housing is connected to the first housing frame and defines a first installation space, and the first cover body is disposed in the first installation space.

10. The waterproof heat dissipation assembly of claim 9, further comprising a fluid driving device, wherein the fluid driving device is connected to the first housing frame, and configured to drive the fluid to flow along the flow direction or drive the fluid in a direction reverse to the flow direction.

11. The waterproof heat dissipation assembly of claim 9, further comprising a second cover body and a second housing, wherein the second cover body is connected to the second housing and defines a second installation space, the fluid driving device is disposed in the second installation space, and the second installation space communicates with the first installation space.

12. The waterproof heat dissipation assembly of claim 11, further comprising a second housing frame rotatably connected to the first housing frame and the second housing.

13. The waterproof heat dissipation assembly of claim 11, further comprising a filtering member disposed between the fluid driving device and the plurality of waterproof deflectors.

14. A cabinet comprising:
a cabinet body having an opening; and
a waterproof heat dissipation assembly pivotally connected to the cabinet body and configured to cover the opening, the waterproof heat dissipation assembly comprising:
a plurality of waterproof deflectors, each waterproof deflector comprising:
a body comprising a first end and a second end disposed opposite each other, a flow direction being defined from the first end toward the second end;
a baffle connected to the second end of the body, the baffle being configured to block target objects carried by a fluid flowing along the flow direction; and
wherein an angle between the baffle and the second end is about 60° to about 120°, and the first end is formed with a notch configured to allow blocked target objects to be discharged;
a mounting plate provided with a plurality of mounting slots arranged at intervals, each of the plurality of mounting slots extending in a same direction, the plurality of waterproof deflectors being inserted into the plurality of mounting slots, respectively; and
a first cover body surrounding the mounting plate and the plurality of waterproof deflectors on an outer side of the mounting plate.

15. The cabinet of claim 14, further comprising a first housing and a first housing frame, wherein the first housing is connected to the first housing frame and defines a first installation space, and the first cover body is disposed in the first installation space.

16. The cabinet of claim 14, further comprising a fluid driving device connected to the first housing frame and configured to drive fluid to flow along the flow direction or in a reverse direction relative to the flow direction.

17. The cabinet of claim 14, further comprising a second cover body and a second housing, wherein the second cover body is connected to the second housing to define a second installation space, and the fluid driving device is disposed in the second installation space, the second installation space being in communication with the first installation space.

18. The cabinet of claim 14, further comprising a second housing frame pivotally connected to the first housing frame and the second housing.

19. The cabinet of claim 14, further comprising a filtering member disposed between the fluid driving device and the plurality of waterproof deflectors.
